(19) United States
(12) Patent Application Publication
(10) Pub. No.: US 2026/0163539 A1
(43) Pub. Date: Jun. 11, 2026

(54) SOURCE DRIVER INCLUDING 1-BIT EXTENDED INTERPOLATION AMPLIFIER

(71) Applicant: Samsung Electronics Co., Ltd., Suwon-si (KR)

(72) Inventors: Jeong CHO, Suwon-si (KR); Seung Hee KUK, Suwon-si (KR); Seung-Hoon BAEK, Suwon-si (KR)

(73) Assignee: Samsung Electronics Co., Ltd., Suwon-si (KR)

(21) Appl. No.: 19/267,972

(22) Filed: Jul. 14, 2025

(30) Foreign Application Priority Data
Dec. 11, 2024 (KR) 10-2024-0183810

(51) Int. Cl. H03F 3/45

(52) U.S. Cl. CPC H03F 3/45475; H03F 3/45179

(57) ABSTRACT

A source driver comprises an input voltage selector receiving a first gamma voltage, a second gamma voltage having a voltage level different from that of the first gamma voltage, and interpolation data, and outputting a plurality of input voltages in accordance with the interpolation data and based on the first and second gamma voltages, and an interpolation amplifier including a first input circuit including a first differential input pair receiving a first input voltage equal to the first gamma voltage, and has a first transconductance value. The interpolation amplifier includes a second input circuit including a second differential input pair receiving a second input voltage corresponding to a least significant bit of the interpolation data, and has a second transconductance value. The interpolation amplifier includes a third input circuit including a third differential input pair receiving a third input voltage, and has a third transconductance value.

### CROSS-REFERENCE TO RELATED APPLICATION

This U.S. non-provisional application claims priority under 35 U.S.C. 119 from Korean Patent Application No. 10-2024-0183810 filed on Dec. 11, 2024, in the Korean Intellectual Property Office, the entire contents of which are herein incorporated by reference.

### BACKGROUND

Example embodiments relate to a source driver including a 1-bit extended interpolation amplifier.

Display devices used in electronic devices that display images, such as TVs, laptop computers, monitors, and mobile devices, include a Liquid Crystal Display (LCD) device and/or an Organic Light Emitting Display (OLED) device. The display device may include a display panel having a plurality of pixels, and gate and source drivers for applying electrical signals to the plurality of pixels, and an image may be implemented by the electrical signals provided by the gate and source drivers to the plurality of pixels. Studies are presently being conducted regarding the refresh rate and resolution of the display device to improve a performance of the display device.

The source driver may generate a gray scale voltage corresponding to a corresponding pixel of the plurality of pixels by receiving a plurality of gamma voltages to apply the electrical signals to the plurality of pixels. In order to limit increase in a chip size, the source driver is provided with an interpolation amplifier that may receive a plurality of gamma voltages and generate various gray scale voltages by interpolating the received gamma voltages.

### SUMMARY

Example embodiments provide a source driver including a 1-bit extended interpolation amplifier.

Example embodiments are not limited to those mentioned above and additional embodiments, which are not mentioned herein, will be clearly understood by those skilled in the art from the following description of the present disclosure.

According to some example embodiments, a source driver includes an input voltage selector configured to receive a first gamma voltage, a second gamma voltage having a voltage level different from that of the first gamma voltage, and interpolation data, and configured to output a plurality of input voltages in accordance with the interpolation data and based on the first and second gamma voltages; and an interpolation amplifier including, a first input circuit including a first differential input pair configured to receive a first input voltage equal to the first gamma voltage among the plurality of input voltages, the first input circuit having a first transconductance value, a second input circuit including a second differential input pair configured to receive a second input voltage corresponding to a least significant bit of the interpolation data among the plurality of input voltages, the second input circuit having a second transconductance value, and a third input circuit including a third differential input pair configured to receive a third input voltage among the plurality of input voltages, the third input circuit having a third transconductance value. The first transconductance value and the second transconductance value are smaller than the third transconductance value.

According to some example embodiments, a source driver includes an interpolation amplifier configured to receive a plurality of input voltages repeatedly, the plurality of input voltages including at least one of a first gamma voltage or a second gamma voltage having a voltage level different from that of the first gamma voltage, and configured to generate an output voltage corresponding to interpolation data of N bits (Nis a natural number of 2 or more) based on the plurality of input voltages. The interpolation amplifier includes a plurality of differential input pairs less than 2^{N}, the plurality of differential input pairs are configured to receive the plurality of input voltages, and the plurality of differential input pairs include a first differential input pair including a first input transistor configured to receive a first input voltage of the plurality of input voltages, a second differential input pair including a second input transistor configured to receive a second input voltage of the plurality of input voltages, and a third differential input pair including a third input transistor configured to receive a third input voltage of the plurality of input voltages. A ratio of a channel width to a channel length of each of the first input transistor and the second input transistor is less than that of the third input transistor.

According to some example embodiments, a source driver includes an input voltage selector configured to receive a first gamma voltage, a second gamma voltage having a voltage level different from that of the first gamma voltage, and interpolation data, and configured to output a plurality of input voltages in accordance with the interpolation data and based on the first and second gamma voltages; and an interpolation amplifier including a first input circuit including a first differential input pair configured to receive a first input voltage of the plurality of input voltages and a first current source configured to generate a first bias current, and a second input circuit including a second differential input pair configured to receive a second input voltage of the plurality of input voltages and a second current source configured to generate a second bias current. A ratio of a channel width to a channel length of a first input transistor of the first differential input pair is less than that of a second input transistor of the second differential input pair, the first input transistor is configured to receive the first input voltage, the second input transistor is configured to receive the second input voltage, and a magnitude of the first bias current is less than a magnitude of the second bias current.

According to some example embodiments, a method of operating a source driver includes receiving, using an input voltage selector of the source driver, a first gamma voltage, a second gamma voltage having a voltage level different from that of the first gamma voltage, and interpolation data, outputting, using the input voltage selector, a plurality of input voltages in accordance with the interpolation data and based on the first and second gamma voltages, receiving, using an interpolation amplifier of the source driver, a first input voltage equal to the first gamma voltage among the plurality of input voltages, the interpolation amplifier including a first input circuit having a first differential input pair configured to receive the first input voltage, and the first input circuit having a first transconductance value, receiving, using the interpolation amplifier, a second input voltage corresponding to a least significant bit of the interpolation data among the plurality of input voltages, the interpolation amplifier including a second input circuit including a second differential input pair configured to receive the second input voltage, the second input circuit having a second transconductance value, and receiving, using the interpolation amplifier, a third input voltage among the plurality of input voltages, the interpolation amplifier including a third input circuit having a third differential input pair configured to receive the third input voltage, the third input circuit having a third transconductance value. The first transconductance value and the second transconductance value are smaller than the third transconductance value. According to some example embodiments, a magnitude of the first transconductance value is half of a magnitude of the second transconductance value. According to some example embodiments, the interpolation data includes N bits (N is a natural number of 2 or more), and the interpolation amplifier includes less than 2^{N} differential input pairs, the 2^{N} differential input pairs are configured to receive the plurality of input voltages, and the 2^{N} differential input pairs include the first differential input pair, the second differential input pair, and the third differential input pair. According to some example embodiments, a number of all differential input pairs configured to receive the plurality of input voltages in the interpolation amplifier is 2(^{N-1})+1. According to some example embodiments, the first to third differential input pairs each include a first input transistor, a second input transistor, and a third input transistor configured to receive the first input voltage, the second input voltage and the third input voltage, respectively, and a ratio of a channel width to a channel length of the first input transistor and the second input transistor is less than that of the third input transistor.

Discussion of the other example embodiments are included in the detailed description and drawings.

### BRIEF DESCRIPTION OF THE DRAWINGS

FIG. 1 is a block diagram illustrating a display system that includes a display device.

FIG. 2 is a block diagram illustrating a display device that includes a display driving circuit.

FIG. 3 is a block diagram illustrating a structure of the source driver of FIG. 2.

FIG. 4 is a block diagram illustrating an interpolation circuit.

FIGS. 5 and 6 are circuit diagrams illustrating a structure of an interpolation amplifier included in an interpolation circuit.

FIG. 7 is a block diagram illustrating an operation of an interpolation amplifier.

FIG. 8 is a table illustrating an operation of the interpolation amplifier of FIG. 7.

FIG. 9 is a block diagram illustrating an operation of an interpolation amplifier.

FIG. 10 is a table illustrating an operation of the interpolation amplifier of FIG. 9.

FIG. 11 is a circuit diagram illustrating a structure of a 1-bit extended interpolation amplifier included in an interpolation circuit.

FIG. 12 is a block diagram illustrating an operation of a 1-bit extended interpolation amplifier.

FIG. 13 is a table illustrating an operation of the 1-bit extended interpolation amplifier of FIG. 12.

FIG. 14 is a table for comparing a comparison target interpolation amplifier with a 1-bit extended interpolation amplifier.

FIG. 15 is a circuit diagram illustrating a structure of a 1-bit extended interpolation amplifier included in an interpolation circuit.

### DETAILED DESCRIPTION OF EXAMPLE EMBODIMENTS

Hereinafter, the example embodiments according to the technical aspects of the present disclosure will be described with reference to the accompanying drawings.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

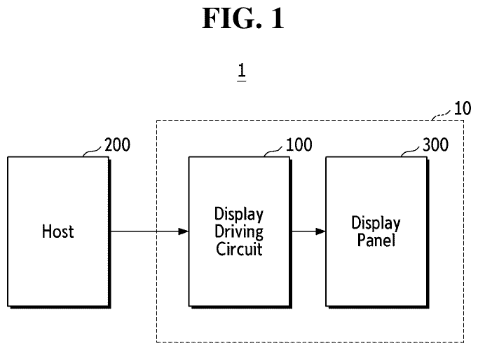

FIG. 1 is a block diagram illustrating a display system that includes a display device.

Referring to FIG. 1, a display system 1 may include a display device 10 and a host 200, and the display device 10 may include a display driving circuit 100 and a display panel 300.

The host 200 may generate image data to be displayed on the display panel 300 and provide the image data and a control command to the display driving circuit 100. For example, the control command may include setting information on luminance, gamma, frame frequency, operation mode of the display driving circuit 100, etc. The host 200 may provide a clock signal or a synchronization signal to the display driving circuit 100.

The host 200 may be a graphics processing unit (GPU), but is not limited thereto, and the host 200 may be implemented as various types of processors such as a central processing unit (CPU), a microprocessor, a multimedia processor, and an application processor. Also, the host 200 may be implemented as an integrated circuit (IC) or a system on chip (SoC).

The display device 10 may display an image corresponding to the image data provided from the host 200. The display device 10 may be a device in which the display driving circuit 100 and the display panel 300 are implemented as a single module. For example, the display driving circuit 100 may be mounted on a substrate of the display panel 300, or the display driving circuit 100 and the display panel 300 may be electrically connected to each other through a connection member such as a flexible printed circuit board (FPCB).

The display panel 300 is a display unit on which an actual image is displayed, and may be one of display devices, which display a two-dimensional image by receiving an electrically transmitted image signal, such as an organic light emitting diode (OLED) display, a thin film transistor-liquid crystal display (TFT LCD), a field emission display and a plasma display panel (PDP). The display driving circuit 100 may convert the image data received from the host 200 into a plurality of analog signals for driving the display panel 300, for example, a plurality of source voltages, and may supply the plurality of converted analog signals to the display panel 300. Accordingly, an image corresponding to the image data may be displayed on the display panel 300.

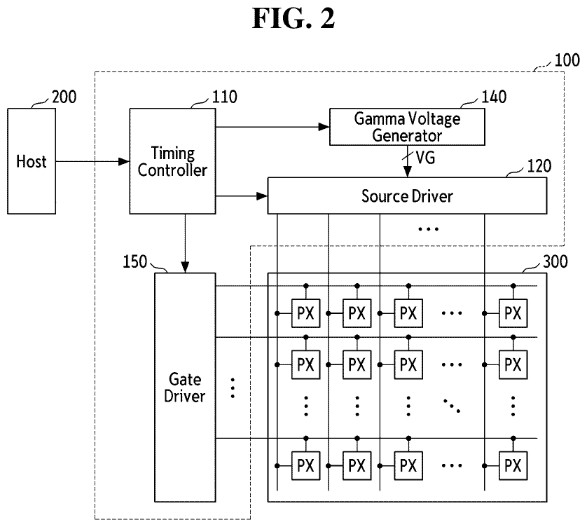

FIG. 2 is a block diagram illustrating a display device that includes a display driving circuit.

Referring to FIG. 2, the display driving circuit 100 may include a source driver 120, a gate driver 150, a gamma voltage generator 140, and a timing controller 110.

A plurality of source lines and a plurality of gate lines may cross each other on the display panel 300, and pixels PX may be disposed in a matrix form for each crossing area. The display panel 300 may be a flat display panel such as a TFT-LCD, a PDP, an LED display, or an OLED, but is not limited thereto.

Each pixel PX may be connected to any one of the source lines and any one of the gate lines. Each pixel PX may be electrically connected to the source line to receive a source voltage from the source line in response to a gate pulse input through the gate lines. A display operation of the display panel 300 may be performed as one operation of the source driver 120 and the gate driver 150 under the control of the timing controller 110.

The source driver 120 may convert pixel data PD, which is a digital signal, into a source voltage for image display in accordance with a data timing control signal applied from the timing controller 110 during the display operation and supply the converted pixel data PD to the source lines.

The gate driver 150 may generate a gate pulse for image display based on a gate control signal during the display operation and then sequentially supply the gate pulse to the gate lines in a row sequential manner.

The timing controller 110 may generate a data control signal for controlling an operation timing of the source driver 120 and a gate control signal for controlling an operation timing of the gate driver 150 based on timing signals such as a vertical synchronization signal, a horizontal synchronization signal, a dot clock signal and a data enable signal.

The display device 10 may display an image in units of frames. The time required to display one frame may be defined as a vertical period, and the vertical period may be determined by a refresh rate of the display device 10. For example, when the refresh rate of the display device 10 is 60 Hz, the vertical period may be 1/60 second, about 16.7 msec, and when the refresh rate of the display device 10 is 120 Hz, the vertical period may be 1/120 second, or about 8.3 msec.

During one vertical period, the gate driver 150 may scan each of the plurality of gate lines. The time for the gate driver 150 to scan each of the plurality of gate lines may be defined as a horizontal period, and during one horizontal period, the source driver 120 may input a gray scale voltage to the pixels PX. The gray scale voltage may be a voltage output by the source driver 120 based on the pixel data PD, and brightness of each of the pixels PX may be determined by the gray scale voltage.

The gamma voltage generator 140 may generate a plurality of gamma voltages VG under the control of the timing controller 110. The plurality of generated gamma voltages VG may be provided to the source driver 120 through a plurality of gamma lines. For example, the gamma voltage generator 140 may receive information on gamma characteristics of the display device 10 from the timing controller 110 and generate a plurality of gamma voltages VG suitable for a gamma curve according to the gamma characteristics.

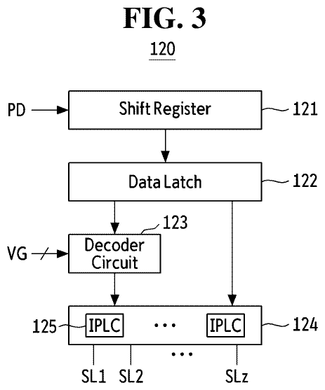

FIG. 3 is a block diagram illustrating a structure of the source driver 120 of FIG. 2.

Referring to FIG. 3, the source driver 120 may include a shift register 121, a data latch 122, a decoder circuit 123, and an interpolation unit 124. The interpolation unit 124 may include a plurality of interpolation circuits including an interpolation circuit 125.

The shift register 121 may receive the pixel data PD and control an operation timing of each of a plurality of sampling circuits included in the data latch 122 in response to the data timing control signal. The data timing control signal may be a signal having a period.

The data latch 122 may sample and store the pixel data PD in a shift order of the shift register 121. The data latch 122 may output a portion of the sampled pixel data PD to the decoder circuit 123 and output the other portion to the interpolation unit 124.

The decoder circuit 123 may be a digital-analog converter. The decoder circuit 123 may receive the pixel data PD from the data latch 122, and may receive a plurality of gamma voltages VG from a gamma voltage generator (140 of FIG. 2) through a plurality of gamma lines. The number of the plurality of gamma voltages VG may be determined depending on the number of bits of the pixel data PD received by the decoder circuit 123. For example, when the pixel data PD received by the decoder circuit 123 is 8-bit data, the number of the plurality of gamma voltages VG may be 256 or less. As another example, when the pixel data PD is 10-bit data, the number of the plurality of gamma voltages VG may be 1024 or less.

The interpolation unit 124 may include a plurality of interpolation circuits implemented as operational amplifiers, and the interpolation circuits may be connected to a plurality of source lines SL1 to SLz. The decoder circuit 123 may select at least a portion of the plurality of gamma voltages VG based on the received pixel data PD, and may provide the selected portion to each of the plurality of interpolation circuits as input voltages VL and VH.

Each of the plurality of interpolation circuits may interpolate the input voltages VL and VH provided from the decoder circuit 123 and output the same to the plurality of source lines SL1 to SLz as gray scale voltages. In this case, each of the plurality of interpolation circuits may generate various gray scale voltages between the input voltages VL and VH by interpolating the input voltages VL and VH provided from the decoder circuit 123. Accordingly, when the pixel data PD is 10-bit data, each of the plurality of interpolation circuits may output one of 1024 gray scale voltages VG even though the number of the plurality of gamma lines for inputting the plurality of gamma voltages VG to the decoder circuit 123 is smaller than 1024. When the plurality of interpolation circuits are implemented by the above interpolation method, a chip size of the display driving circuit 100 may be reduced by removing some of the plurality of gamma lines.

Hereinafter, the interpolation circuit 125 of the plurality of interpolation circuits will be described, but it is apparent to those skilled in the art that the description of the interpolation circuit 125 may be also applied to each of the plurality of interpolation circuits.

The components 121, 122, 123 and 124 included in the source driver 120 are not limited to those shown in FIG. 3, and may be modified depending on application and/or design.

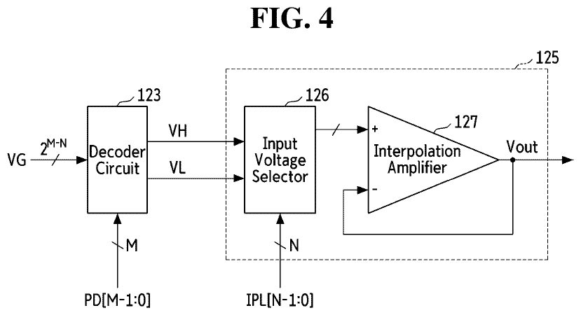

FIG. 4 is a block diagram illustrating an interpolation circuit.

Referring to FIG. 4, the interpolation circuit 125 may include an interpolation amplifier 127 and an input voltage selector 126. Although a circuit for outputting one source line is shown in FIG. 4, it is apparent to those skilled in the art that the source driver may include a plurality of interpolation circuits to drive a plurality of source lines, and the description of the interpolation circuit 125 may be applied to each of the plurality of interpolation circuits. The decoder circuit 123 may receive a plurality of gamma voltages VG and pixel data PD[M−1:0] of M bits (M is a natural number of 4 or more, for example, 10), and may select two voltages of the plurality of gamma voltages VG in response to the pixel data PD[M−1:0]. The decoder circuit 123 may output the selected two voltages as a first gamma voltage VH and a second gamma voltage VL. The decoder circuit 123 may be an M-N bit decoder.

The decoder circuit 123 may receive 2^{M-N} gamma voltages VG, and may select the first gamma voltage VH and the second gamma voltage VL in response to some upper bits PD[M−1:N] of the pixel data PD[M−1:0], but is not limited thereto. The decoder circuit 123 may receive 2^{M} gamma voltages VG or less.

The first gamma voltage VH and the second gamma voltage VL may be voltages, of which voltage levels (voltage magnitudes) are adjacent to each other, among the plurality of gamma voltages VG, and the voltage level of the first gamma voltage VH may be higher than the voltage level of the second gamma voltage VL, but example embodiments are not limited thereto. The voltage level of the second gamma voltage VL may be higher than the voltage level of the first gamma voltage VH. The interpolation circuit 125 may generate and output a gray scale voltage having a value between the first gamma voltage VH and the second gamma voltage VL based on lower N bits (referred to as ‘interpolation data’) of the pixel data PD[M−1:0] of M bits. For example, the interpolation circuit 125 may output gray scale voltages having various levels as much as 2^{N} based on the first gamma voltage VH and the second gamma voltage VL. The gray scale voltage of the interpolation circuit 125, e.g., an output voltage Vout, may be output to the source line SL1 of the display panel. The output voltage Vout may be a gray scale voltage that is expressed by the pixel data PD[M−1:0] of M bits. In other words, the output voltage Vout may be a gray scale voltage corresponding to the pixel data PD[M−1:0] of M bits. The input voltage selector 126 may selectively repeat and distribute the first gamma voltage VH and the second gamma voltage VL in accordance with a logic combination of interpolation data IPL[N−1:0] that are lower N bits of the pixel data PD[M−1:0] of M bits to output a plurality of distributed voltages. Accordingly, the distributed voltages may be one of the first gamma voltage VH and the second gamma voltage VL. The input voltage selector 126 may provide the distributed voltages to the interpolation amplifier 127 as input voltages. For example, the input voltage selector 126 may output the distributed voltages of 2^{N} or less. The interpolation amplifier 127 may receive the distributed voltages output from the input voltage selector 126 as input voltages, and may interpolate the input voltages to generate output voltages Vout that may have various levels as much as 2^{N}. The output voltage Vout may be referred to as a gray scale voltage. The output voltage Vout of 2^{N} may have a voltage level of the first gamma voltage VH or a voltage level between the first gamma voltage VH and the second gamma voltage VL, but is not limited thereto. The output voltage Vout may have a voltage level of the second gamma voltage VL or a voltage level between the first gamma voltage VH and the second gamma voltage VL. The interpolation amplifier 127 may include a plurality of non-inverted input terminals (+), and distributed voltages output from the input voltage selector 126 through the plurality of non-inverted input terminals (+) may be applied as a plurality of input voltages. An inverted input terminal (−) of the interpolation amplifier 127 may be connected to an output terminal, and thus the interpolation amplifier 127 may operate as a buffer.

The interpolation amplifier 127 may include k number of input circuits (k is a natural number of 2^{N} or less), and may output an output voltage Vout, which may have various levels as much as 2^{N}, based on input voltages provided to a differential input pair.

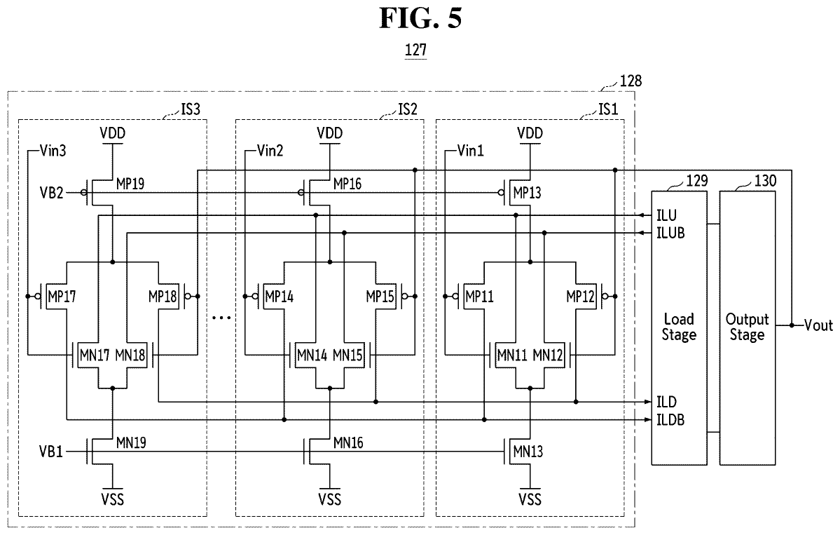

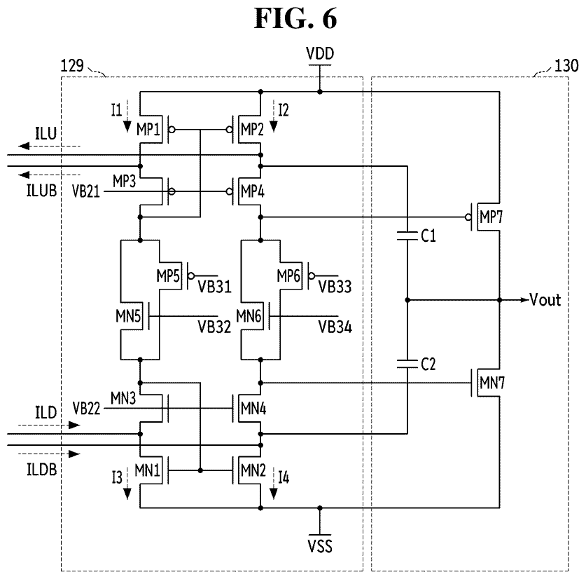

FIGS. 5 and 6 are circuit diagrams illustrating a structure of an interpolation amplifier included in an interpolation circuit.

Referring to FIGS. 5 and 6, the interpolation amplifier 127 may include an input stage 128, a load stage 129, and an output stage 130. The input stage 128 may include a plurality of input circuits IS1 to IS3 having a rail-to-rail structure. The input stage 128 having three input circuits is shown in FIG. 5. However, the number of input circuits is not limited to three, and the number of input circuits may be more than or less than three depending on the number of received input voltages depending on application and/or design.

Among the plurality of input circuits IS1 to IS3, the first input circuit IS1 may include a first differential input pair that includes NMOS transistors MN11 and MN12 and a second differential input pair that includes PMOS transistors MP11 and MP12. Also, the first input circuit IS1 may include current sources MN13 and MP13 connected to respective first and second differential input pairs in series and implemented as NMOS and PMOS transistors to generate a bias current. The second input circuit IS2 may include a first differential input pair that includes NMOS transistors MN14 and MN15 and a second differential input pair that includes PMOS transistors MP14 and MP15. Also, the second input circuit IS2 may include current sources MN16 and MP16 connected to respective first and second differential input pairs in series and implemented as NMOS and PMOS transistors to generate a bias current. The third input circuit IS3 may include a first differential input pair that includes NMOS transistors MN17 and MN18 and a second differential input pair that includes PMOS transistors MP17 and MP18. Furthermore, the third input circuit IS3 may include current sources MN19 and MP19 connected to respective first and second differential input pairs in series and implemented as NMOS and PMOS transistors to generate a bias current. The structure of the plurality of input circuits shown in FIG. 5 is an example, and various modifications may be made in the structure of the input circuits depending on application and/or design.

The NMOS and PMOS transistors MN11 and MP11 of the first and second differential input pairs of the first input circuit IS1 may receive a first input voltage Vin1 as a gate voltage. Other NMOS and PMOS transistors MN12 and MP12 of the first and second differential input pairs may receive the output voltage Vout as a gate voltage. The current sources MN13 and MP13 may respectively receive bias voltages VB1 and VB2 as gate voltages to generate the bias current. A magnitude of the bias current may be adjusted by adjusting a magnitude of the bias voltage. The NMOS and PMOS transistors MN14 and MP14 of the first and second differential input pairs of the second input circuit IS2 may receive a second input voltage Vin2 as a gate voltage. Other NMOS and PMOS transistors MN15 and MP15 of the first and second differential input pairs may receive the output voltage Vout as a gate voltage. The current sources MN16 and MP16 may respectively receive the bias voltages VB1 and VB2 as gate voltages to generate the bias current. The NMOS and PMOS transistors MN17 and MP17 of the first and second differential input pairs of the third input circuit IS3 may receive a third input voltage Vin3 as a gate voltage. Other NMOS and PMOS transistors MN18 and MP18 of the first and second differential input pairs may receive the output voltage Vout as a gate voltage. The current sources MN19 and MP19 may respectively receive the bias voltages VB1 and VB2 as gate voltages to generate the bias current.

The input stage 128 may provide or receive load currents ILU, ILUB, ILD and ILDB to or from the load stage 129. Magnitudes of the load currents ILU, ILUB, ILD and ILDB may be determined by a difference between the input voltages Vin1 to Vin3 and the output voltage Vout.

The load stage 129 may provide or receive load currents ILU, ILUB, ILD, and ILDB to or from the input stage 128. The load stage 129 may be implemented in a folded cascode structure. The load stage 129 may include a plurality of NMOS and PMOS transistors MP1, MP2, MP3, MP4, MN1, MN2, MN3 and MN4 constituting a current mirror, and thus may perform a current mirroring operation. Currents I1, I2, I3 and I4 flowing in the load stage 129 may be controlled by bias voltages VB21, VB22, VB31, VB32, VB33 and VB34. The bias voltage VB21 may be provided as gate voltage to the PMOS transistors MP3 and MP4. The bias voltage VB22 may be provided as gate voltage to the NMOS transistors MN3 and MN4. The bias voltage VB31 may be provided as gate voltage to the PMOS transistor MP5. The bias voltage VB32 may be provided as gate voltage to the NMOS transistor MN5. The bias voltage VB33 may be provided as gate voltage to the PMOS transistor MP6. The bias voltage VB34 may be provided as gate voltage to the NMOS transistor MN6. The load stage 129 may amplify a signal received from the input stage 128 and provide the amplified signal to the output stage 130. The output stage 130 may output the output voltage Vout through an output terminal in accordance with the signal received from the load stage 129. The output stage 130 may further include capacitors C1 and C2 for stabilizing the output voltage Vout. The load stage 129 and the output stage 130, which are shown in FIG. 6, are only examples, and may be implemented in various ways different from those shown in FIG. 6 depending on the application and/or design. In some example embodiments, the load stage 129 may be omitted.

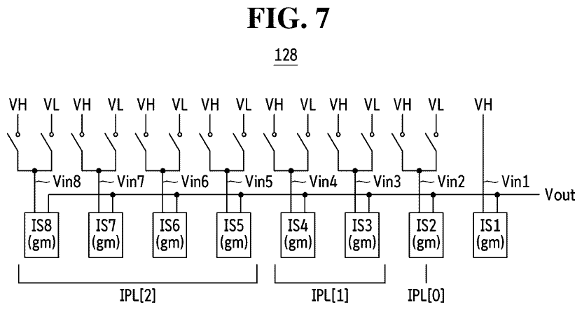

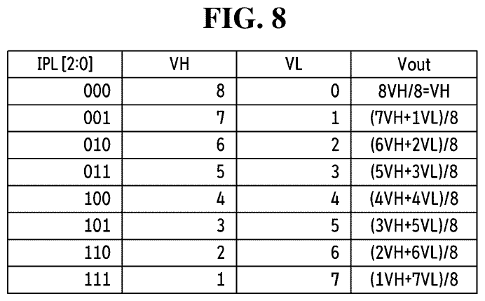

FIG. 7 is a block diagram illustrating an operation of an interpolation amplifier. FIG. 8 is a table illustrating an operation of the interpolation amplifier of FIG. 7.

Referring to FIGS. 7 and 8, the input stage 128 of the interpolation amplifier 127 may include a plurality of input circuits IS1 to IS8. The input stage 128 having eight input circuits is shown in FIG. 7, but the number of input circuits is not limited to eight. The number of input circuits may be more than or less than eight depending on the number of received input voltages, according to some example embodiments. FIG. 7 illustrates an example of an interpolation amplifier that generates an output voltage according to interpolation data IPL[2:0] of 3 bits.

The input stage 128 may receive eight input voltages in accordance with the interpolation data IPL[2:0] of 3 bits. As described above, the input voltages are a plurality of distributed voltages output by selectively repeating and distributing the first gamma voltage VH and the second gamma voltage VL. The first input circuit IS1 may receive the first gamma voltage VH as the first input voltage Vin1 regardless of the interpolation data, but is not limited thereto. According to some example embodiments, the first input circuit IS1 may also receive the second gamma voltage VL. Hereinafter, for convenience of description, it is assumed that the first input circuit IS1 receives the first gamma voltage VH. The second input circuit IS2 may receive the gamma voltage corresponding to the 0th bit IPL[0], which is the least significant bit of the interpolation data IPL[2:0], in the first gamma voltage VH or the second gamma voltage VL. The third and fourth input circuits IS3 and IS4 may receive the gamma voltage corresponding to the first bit IPL[1] of the interpolation data IPL[2:0], in the first gamma voltage VH or the second gamma voltage VL. The third and fourth input circuits IS3 and IS4 may receive the same gamma voltage. The fifth to eighth input circuits IS5 to IS8 may receive the gamma voltage corresponding to the second bit IPL[2] of the interpolation data IPL[2:0], in the first gamma voltage VH or the second gamma voltage VL. The fifth to eighth input circuits IS5 to IS8 may receive the same gamma voltage.

Each of the input circuits IS1 to IS8 may have a unique transconductance value. The transconductance value may determine a ratio of a magnitude of a voltage received by each of the differential input pairs of the input circuits IS1 to IS8 to a magnitude of a current to be output therefrom. For example, when the transconductance value of any input circuit (referred to as an input circuit A) is half of that of another input circuit (referred to as an input circuit B), and the input circuit A and the input circuit B receive a voltage of the same magnitude, a magnitude of a current output by the input circuit A is half of a magnitude of a current output by the input circuit B.

Referring to the following equation, the transconductance value of the input circuit may vary depending on the magnitude of the bias current and operating characteristics of the NMOS and PMOS transistors MN11, MN12, MP11 and MP12 constituting the differential input pairs in the transistor (e.g., the first input circuit IS1 of FIG. 5) constituting the differential input pair.

$$ℊ m ∝ \sqrt{( \frac{W}{L} ) * Ib} \qquad [ Equation 1 ]$$

gm denotes the transconductance value, W denotes a channel width of the transistors constituting the differential input pair of the corresponding input circuit, L denotes a channel length of the transistors constituting the differential input pair of the corresponding input circuit, and Ib denotes a magnitude of a bias current of the corresponding input circuit.

The output voltage of the interpolation amplifier may be expressed by the following equation.

$$Vout = \frac{( {Σ}_{i = 1}^{k} ℊ {m}_{i} * V H ( i ) ) * V H + ( {Σ}_{i = 1}^{k} ℊ {m}_{i} * VL ( i ) ) * VL}{( {Σ}_{i = 1}^{k} ℊ {m}_{i} * V H ( i ) ) + ( {Σ}_{i = 1}^{k} ℊ {m}_{i} * VL ( i ) )} \qquad [ Equation 2 ]$$

i denotes the corresponding input circuit, k denotes the total number of input circuits, gmᵢ denotes the transconductance value of the corresponding input circuit, VH(i) denotes a function that has a value of 1 when the corresponding input circuit receives the first gamma voltage VH and has a value of 0 when the corresponding input circuit receives the second gamma voltage VL, VL(i) denotes a function that has a value of 0 when the corresponding input circuit receives the first gamma voltage VH and has a value of 1 when the corresponding input circuit receives the second gamma voltage VL, VH denotes the magnitude of the first gamma voltage VH, and VL denotes the magnitude of the second gamma voltage VL.

When transconductance values of all input circuits of the interpolation amplifier are the same, the above equation may be simplified as expressed by the following equation.

$$Vout = \frac{n ( VH ) * VH + n ( VL ) * VL}{n ( VH ) + n ( VL )} \qquad [ Equation 3 ]$$

n(VH) denotes the number of received first gamma voltages VH, n(VL) denotes the number of received second gamma voltages VL, VH denotes the magnitude of the first gamma voltage VH, and VL denotes the magnitude of the second gamma voltage VL. The result of calculating a magnitude of an output voltage, which is generated by the interpolation amplifier of FIG. 7 in accordance with the interpolation data IPL[2:0] of 3 bits, in accordance with the Equation 3 is shown in the table of FIG. 8.

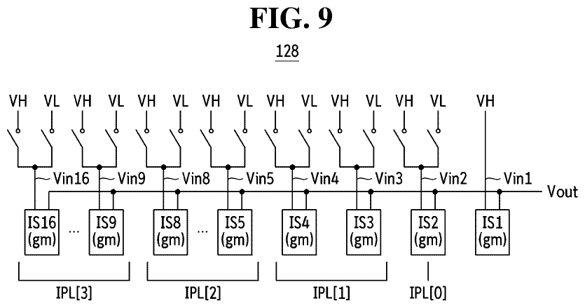

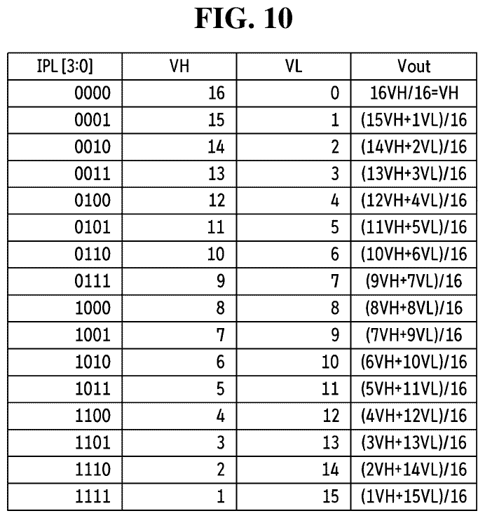

FIG. 9 is a block diagram illustrating an operation of an interpolation amplifier. FIG. 10 is a table illustrating an operation of the interpolation amplifier of FIG. 9.

The input stage 128 of the interpolation amplifier 127 in FIG. 9 may be same as or similar in some respects to the input stage 128 of the interpolation amplifier 127 in FIG. 7, and therefore may be best understood with reference thereto where like numerals indicate like elements not described again in detail. Referring to FIGS. 9 and 10, the input stage 128 may include a plurality of input circuits IS1 to IS16. The input stage 128 having 16 input circuits is shown in FIG. 9, but the number of input circuits is not limited to 16. The number of input circuits may be more than or less than 16 depending on the number of received input voltages according to some example embodiments. FIG. 9 illustrates an example of an interpolation amplifier that generates an output voltage according to interpolation data IPL[3:0] of 4 bits.

The interpolation amplifier of FIG. 9 may further include ninth to sixteenth input circuits IS9 to IS16. The ninth to sixteenth input circuits IS9 to IS16 may receive the gamma voltage corresponding to the third bit IPL[3] of the interpolation data IPL[3:0], in the first gamma voltage VH or the second gamma voltage VL. The ninth to sixteenth input circuits IS9 to IS16 may receive the same gamma voltage. The result of calculating a magnitude of an output voltage, which is generated by the interpolation amplifier in accordance with the interpolation data IPL[3:0] of 4 bits, in accordance with the above Equation 3 is shown in the table of FIG. 10.

In FIG. 9, as the interpolation data is increased by one bit from 3 bits to 4 bits, the number of input circuits may be increased by two times.

As the number of bits of pixel data input to the source driver is gradually increased, the number of bits of the interpolation data received by the interpolation amplifier to minimize the size increase in the source driver is also gradually increasing. However, as the number of bits is increased by one bit, the number of input circuits is increased to twice, and an area occupied by the interpolation amplifier in a chip (e.g., the source driver) may increase.

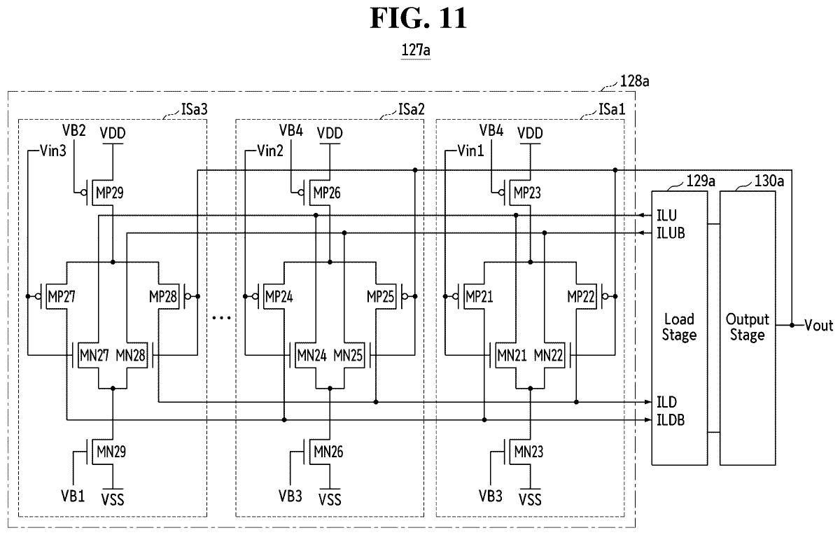

FIG. 11 is a circuit diagram illustrating a structure of a 1-bit extended interpolation amplifier included in an interpolation circuit.

The 1-bit extended interpolation amplifier 127a in FIG. 11 may be same as or similar in some respects to the interpolation amplifier 127 in FIGS. 5 and 6, and therefore may be best understood with reference thereto where like numerals indicate like elements not described again in detail. Referring to FIG. 11, a 1-bit extended interpolation amplifier 127a may include an input stage 128a, a load stage 129a, and an output stage 130a. The input stage 128a may include a plurality of input circuits ISa1 to ISa3. The input stage 128a having three input circuits is shown in FIG. 11, but the number of input circuits is not limited to three. The number of input circuits may be more than or less than three depending on the number of received input voltages according to some example embodiments.

Among the plurality of input circuits ISa1 to ISa3, the first input circuit ISa1 may include a pair of NMOS transistors MN21 and MN22 and a pair of PMOS transistors MP21 and MP22, each constituting a differential input pair. A current source MN23 is connected in series to the differential input pair including the pair of NMOS transistors MN21 and MN22 to generate a bias current and a current source MP23 is connected in series to the differential input pair including the pair of PMOS transistors MP21 and MP22 to generate a bias current. The second input circuit ISa2 may include a pair of NMOS transistors MN24 and MN25 and a pair of PMOS transistors MP24 and MP25, each constituting a differential input pair. A current source MN26 is connected in series to the differential input pair including the pair of NMOS transistors MN24 and MN25 to generate a bias current and a current source MP26 is connected in series to the differential input pair including the pair of PMOS transistors MP24 and MP25 to generate a bias current. The third input circuit ISa3 may include a pair of NMOS transistors MN27 and MN28 and a pair of PMOS transistors MP27 and MP28, each constituting a differential input pair. A current source MN29 is connected in series to the differential input pair including the pair of NMOS transistors MN27 and MN28 to generate a bias current and a current source MP29 connected in series to the differential input pair including the pair of PMOS transistors MP27 and MP28 to generate a bias current.

The NMOS and PMOS transistors MN21 and MP21 constituting the respective differential input pair of the first input circuit ISa1 may receive the first input voltage Vin1 as a gate voltage. Other NMOS and PMOS transistors MN22 and MP22 constituting the respective differential input pair may receive the output voltage Vout as a gate voltage. The current sources MN23 and MP23 connected to the respective differential input pair may receive the bias voltages VB3 and VB4, respectively, as gate voltages to generate the bias current. The NMOS and PMOS transistors MN24 and MP24 constituting the respective differential input pair of the second input circuit ISa2 may receive the second input voltage Vin2 as a gate voltage. Other NMOS and PMOS transistors MN25 and MP25 constituting the respective differential input pair may receive the output voltage Vout as a gate voltage. The current sources MN26 and MP26 connected to the respective differential input pair may receive the bias voltages VB3 and VB4, respectively, as gate voltages to generate the bias current. The NMOS and PMOS transistors MN27 and MP27 constituting the respective differential input pair of the third input circuit ISa3 may receive the third input voltage Vin3 as a gate voltage. Other NMOS and PMOS transistors MN28 and MP28 constituting the respective differential input pair may receive the output voltage Vout as a gate voltage. The current sources MN29 and MP29 connected to the respective differential input pair may receive the bias voltages VB3 and VB4, respectively, as gate voltages to generate the bias current.

According to some example embodiments, the 1-bit extended interpolation amplifier 127a may be obtained by dividing a transconductance value of an input circuit for receiving a first input voltage in the above-described interpolation amplifier (e.g., the interpolation amplifier 127 of FIG. 5). Accordingly, in the 1-bit extended interpolation amplifier 127a, transconductance values of the input circuits may be different. For example, the first input circuit ISa1 and the second input circuit ISa2 may have a first transconductance value, and the other input circuits (e.g., the third input circuit ISa3) except the first input circuit ISa1 and the second input circuit ISa2 may have a second transconductance value greater than the first transconductance value. In some example embodiments, the first transconductance value may be substantially half of the second transconductance value. For the purposes of discussion, it may be assumed that the first transconductance value may be substantially half due to a manufacturing error and/or a measurement error.

According to the Equation 1 described above, the transconductance value of the input circuit is proportional to a square root of a ratio W/L of a channel width to a channel length of a transistor constituting the differential input pair of the input circuit, and is proportional to a square root of the bias current generated by the current source of the input circuit.

According to some example embodiments, the ratio W/L of the channel width to the channel length of the transistors MN21, MN22, MN24, MN25, MP21, MP22, MP24 and MP25 constituting the differential input pair of the first input circuit ISa1 and the second input circuit ISa2 may be smaller than the ratio W/L of the channel width to the channel length of the transistors constituting the differential input pair of the other input circuits (e.g., the third input circuit ISa3) except the first input circuit ISa1 and the second input circuit ISa2, and a magnitude of the bias current by the current sources MN23, MN26, MP23 and MP26 of the first input circuit ISa1 and the second input circuit ISa2 may be smaller than a magnitude of the bias current by the current sources of the other input circuits (e.g., the third input circuit ISa3) except the first input circuit ISa1 and the second input circuit ISa2.

In some example embodiments, the ratio W/L of the channel width to the channel length of the transistors MN21, MN22, MN24, MN25, MP21, MP22, MP24 and MP25 constituting the differential input pair of the first input circuit ISa1 and the second input circuit ISa2 may be substantially half of the ratio W/L of the channel width to the channel length of the transistors constituting the differential input pair of the other input circuits (e.g., the third input circuit ISa3) except the first input circuit ISa1 and the second input circuit Isa2, and a magnitude of the bias current by the bias voltages VB3 and VB4 of the first input circuit ISa1 and the second input circuit ISa2 may be substantially half of a magnitude of the bias current by the bias voltages VB1 and VB2 of the other input circuits (e.g., the third input circuit ISa3) except the first input circuit ISa1 and the second input circuit ISa2.

In order that the ratio W/L of the channel width to the channel length of the transistors MN21, MN22, MN24, MN25, MP21, MP22, MP24 and MP25 constituting the differential input pair of the first input circuit ISa1 and the second input circuit ISa2 may be half of the ratio W/L of the channel width to the channel length of the transistors constituting the differential input pair of the other input circuits (e.g., the third input circuit ISa3) except the first input circuit ISa1 and the second input circuit Isa2, the channel width of the transistors MN21, MN22, MN24, MN25, MP21, MP22, MP24 and MP25 constituting the differential input pair of the first input circuit ISa1 and the second input circuit ISa2 may be reduced to half, or the channel length of the transistors MN21, MN22, MN24, MN24, MP21, MP22, MP24 and MP25 constituting the differential input pair of the first input circuit ISa1 and the second input circuit ISa2 may be increased to substantially twice. In this case, the meaning of substantially twice is used as the meaning including a manufacturing error and a measurement error.

In some example embodiments, the ratio W/L of the channel width to the channel length of the transistors MN21, MN22, MN24, MN25, MP21, MP22, MP24 and MP25 constituting the differential input pair of the first input circuit Isa1 and the second input circuit Isa2 may be substantially ¼ times (0.25 times) of the ratio W/L of the channel width to the channel length of the transistors constituting the differential input pair of the other input circuits (e.g., the third input circuit Isa3) except the first input circuit Isa1 and the third input circuit Isa3. In this case, the meaning of substantially ¼ times (0.25 times) is used as the meaning including a manufacturing error and a measurement error. In some example embodiments, the magnitude of the bias current by the bias voltages VB3 and VB4 of the first input circuit Isa1 and the second input circuit Isa2 may be substantially the same as the magnitude of the bias current by the bias voltages VB1 and VB2 of the other input circuits (e.g., the third input circuit Isa3) except the first input circuit Isa1 and the second input circuit Isa2.

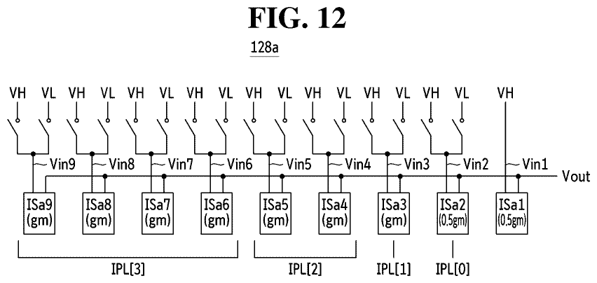

FIG. 12 is a block diagram illustrating an operation of a 1-bit extended interpolation amplifier.

Referring to FIG. 12, the input stage 128a of the 1-bit extended interpolation amplifier 127a may include a plurality of input circuits Isa1 to Isa9. The input stage 128a having nine input circuits is shown in FIG. 12, but the number of input circuits is not limited to nine. The number of input circuits may be more than or less than nine depending on the number of received input voltages according to the embodiments. FIG. 12 illustrates an example of a 1-bit extended interpolation amplifier that generates an output voltage according to interpolation data IPL[3:0] of 4 bits.

The input stage 128a may receive nine input voltages in accordance with the interpolation data IPL[3:0] of 4 bits. The first input circuit Isa1 has a first transconductance value, and may receive the first gamma voltage VH as the first input voltage Vin1 regardless of the interpolation data, but is not limited thereto. The first input circuit Isa1 may also receive the second gamma voltage VL in accordance with some example embodiments. Hereinafter, for convenience of description, it is assumed that the first input circuit ISa1 receives the first gamma voltage VH. The second input circuit ISa2 has a first transconductance value, and may receive the gamma voltage corresponding to the 0th bit IPL[0], which is the least significant bit of the interpolation data IPL[3:0], in the first gamma voltage VH or the second gamma voltage VL. The third input circuit ISa3 has a second inductance value, and may receive the gamma voltage corresponding to the first bit IPL[1] of the interpolation data IPL[3:0], in the first gamma voltage VH or the second gamma voltage VL. The fourth and fifth input circuits ISa4 and ISa5 have a second transconductance value, and may receive the gamma voltage corresponding to the second bit IPL[2] of the interpolation data IPL[3:0], in the first gamma voltage VH or the second gamma voltage VL. The fourth and fifth input circuits ISa4 and ISa5 may receive the same gamma voltage. The sixth to ninth input circuits ISa6 to ISa9 have a second transconductance value, and may receive the gamma voltage corresponding to the third bit IPL[3] of the interpolation data IPL[3:0], in the first gamma voltage VH or the second gamma voltage VL. The sixth to ninth input circuits ISa6 to ISa9 may receive the same gamma voltage.

According to some example embodiments, the first transconductance value may be less than the second transconductance value. In example embodiments, the first transconductance value may be substantially half of the second transconductance value. That is, when the second transconductance value is gm, the first transconductance value may be 0.5 μm.

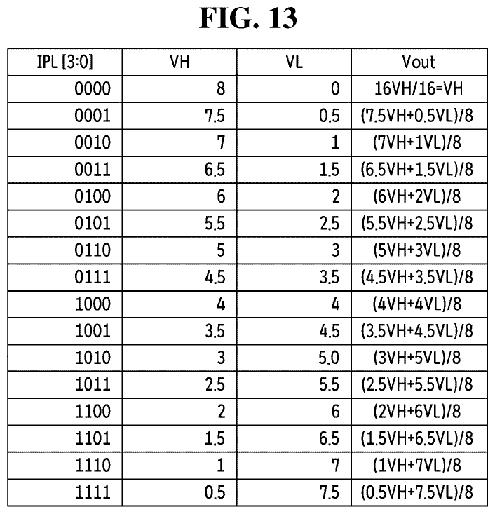

FIG. 13 is a table illustrating an operation of the 1-bit extended interpolation amplifier of FIG. 12.

The result of calculating a magnitude of an output voltage, which is generated by the 1-bit extended interpolation amplifier in accordance with the interpolation data IPL[3:0] of 4 bits, in accordance with the above-described Equation 3 is shown in the table of FIG. 13. Referring to the table of FIG. 13, a magnitude of an output voltage corresponding to each interpolation data is the same as that of FIG. 10. Accordingly, gray scale voltages having 16 different levels according to the interpolation data IPL[3:0] of 4 bits may be output even by nine input circuits.

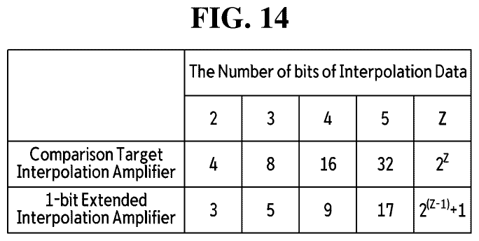

FIG. 14 is a table for comparing a comparison target interpolation amplifier with a 1-bit extended interpolation amplifier.

Referring to FIG. 14, the comparison target interpolation amplifier may be the interpolation amplifier described with reference to FIGS. 5 to 10. The 1-bit extended interpolation amplifier may be the interpolation amplifier described with reference to FIGS. 11 to 13. In response to the interpolation data of z bits (where z is a natural number of 2 or more), the comparison target interpolation amplifier requires 2^{z} differential input pairs, and the 1-bit extended interpolation amplifier may require 2^{(z-1)}+1 differential input pairs.

Even though the interpolation data is increased by only 1 bit, an area occupied by the interpolation amplifier in a chip (e.g., the source driver) may be increased (e.g., increased to about twice). According to some example embodiments, by dividing the transconductance of an input circuit receiving a first input voltage, the 1-bit extended interpolation amplifier may reduce the area occupied by the interpolation amplifier in the chip to about half even though the same number of bits of interpolation data is received as compared with the comparison target interpolation amplifier. As a result, a source driver with a reduced area may be obtained. In addition, the reduced space may be used to improve characteristics of various devices in the source driver.

According to some example embodiments, the 1-bit extended interpolation amplifier may reduce the number of transistors required to implement the interpolation amplifier to about half even though the 1-bit extended interpolation amplifier receives the same number of bits of interpolation data as compared with the comparison target interpolation amplifier. As a result, a source driver with reduced cost may be provided. When the number of transistors required to implement the interpolation amplifier is reduced to about half, input capacitance of the interpolation amplifier is reduced, whereby an interpolation amplifier with improved delay of the output voltage may be obtained. In addition, the number of transistors constituting the current source in the input circuit is reduced to about half, whereby a coupling effect between the bias current lines due to the decrease in parasitic capacitance between the bias current lines may be mitigated.

According to some example embodiments, the 1-bit extended interpolation amplifier may further extend interpolation data by 1 bit while occupying the same area as compared with the comparison target interpolation amplifier. Accordingly, a size of a device such as a decoder circuit in the source driver may be reduced. As a result, a source driver with a reduced area may be obtained.

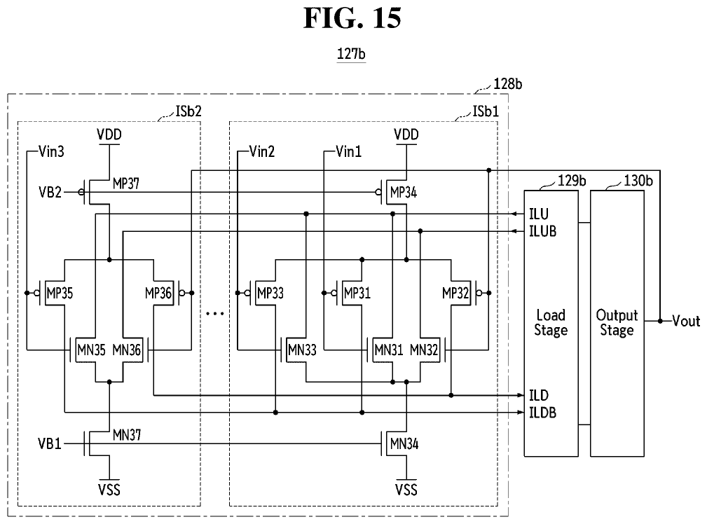

FIG. 15 is a circuit diagram illustrating a structure of a 1-bit extended interpolation amplifier included in an interpolation circuit.

The 1-bit extended interpolation amplifier 127b in FIG. 15 may be same as or similar in some respects to the interpolation amplifiers 127 and in FIGS. 5, 6, and 11, and therefore may be best understood with reference thereto where like numerals indicate like elements not described again in detail. Referring to FIG. 15, the 1-bit extended interpolation amplifier 127b may include an input stage 128b, a load stage 129b, and an output stage 130b. The input stage 128b may include a plurality of input circuits ISb1 and ISb2. The input stage 128b having two input circuits is shown in FIG. 11, but the number of input circuits is not limited to two. The input stage 128b may have input circuits more than two depending on the number of received input voltages according to some example embodiments.

The first input circuit ISb1 may be implemented as a single input circuit such that the respective differential input pairs of the first and second input circuits Isa1 and Isa2 of FIG. 11 shares a current source. In some example embodiments, the first input circuit ISb1 of the plurality of input circuits ISb1 and ISb2 may include NMOS transistors MN31, MN32, and MN33 constituting a differential input pair, and a current source MN34 connected to the differential input pair in series and implemented as an NMOS transistor to generate a bias current. Also, the first input circuit ISb1 may include PMOS transistors MP31, MP32, and MP33 constituting another differential input pair and a current source MP34 connected to the differential input pair in series and implemented as a PMOS transistor to generate a bias current. The second input circuit ISb2 may include NMOS transistors MN35 and MN36 constituting a first differential input pair and PMOS transistors MP35 and MP36 constituting a second differential input pair, and current sources MN37 and MP37 respectively connected in series to the first and second differential input pairs to generate a bias current and implemented as NMOS and PMOS transistors, respectively.

The NMOS transistor MN31, which constitutes one of the plurality of differential input pairs including the NMOS transistors MN31 and MN32 of the first input circuit ISb1, may receive the first input voltage Vin1 as a gate voltage, and the NMOS transistor MN33, which constitutes the other one of the plurality of differential input pairs including the NMOS transistors MN32 and MN33, may receive the second input voltage Vin2 as a gate voltage. The NMOS transistor MN32 shared by the two differential input pairs may receive the output voltage Vout as a gate voltage. The two differential input pairs may share a single current source MN34. The current source MN34 may receive the bias voltage VB1 as a gate voltage to generate a bias current.

The PMOS transistor MP31, which constitutes one of the plurality of differential input pairs including the PMOS transistors MP31 and MP32 of the first input circuit ISb1, may receive the first input voltage Vin1 as a gate voltage, and the PMOS transistor MP33, which constitutes the other one of the plurality of differential input pairs including the PMOS transistors MP32 and MP33, may receive the second input voltage Vin2 as a gate voltage. The PMOS transistor MP32 shared by the two differential input pairs may receive the output voltage Vout as a gate voltage. However, according to some example embodiments, the two differential input pairs may be configured separately without sharing the NMOS or PMOS transistor MN32 or MP32 receiving the output voltage Vout. The two differential input pairs may share a single current source MP34. The current source MP34 may receive the bias voltage VB2 as a gate voltage to generate a bias current.

The NMOS and PMOS transistors MN35 and MP35, which constitute each differential input pair, of the second input circuit ISb2 may receive the third input voltage Vin3 as a gate voltage. The NMOS and PMOS transistors MN36 and MP36, which constitute each differential input pair, may receive the output voltage Vout as a gate voltage. The current sources MN37 and MP37 connected to each differential input pair may receive the bias voltages VB1 and VB2 as gate voltages to generate a bias current.

According to some example embodiments, in the 1-bit extended interpolation amplifier 127b of FIG. 15, two differential input pairs of the first input circuit ISb1 may share a single current source MN34 or MP34. Accordingly, the same bias voltage VB1 may be applied as a gate voltage to the current sources MN34 and MN37 implemented as the NMOS transistors. In addition, the same bias voltage VB2 may be applied as a gate voltage to the current sources MP34 and MP37 implemented as the PMOS transistors. Accordingly, a source driver that includes the 1-bit extended interpolation amplifier 127b has a reduced circuit complexity and occupies a smaller area.

As described herein, any devices, systems, modules, portions, units, controllers, circuits, and/or portions thereof according to any of the example embodiments, and/or any portions thereof (including, without limitation, the display driving circuit 100, the host 200, the display panel 300, source driver 120, the gate driver 150, the gamma voltage generator 140, the timing controller 110, the shift register 121, the data latch 122, the decoder circuit 123, the interpolation unit 124, the interpolation amplifiers 127, 127a, 127b, the input voltage selector 126, the input stages 128, 128a, 128b, the load stage 129, 129a, 129b, the output stage 130, 130a, 130b, the input circuits IS1 to IS16, the input circuits ISa1 to ISa9, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A source driver comprising:
an input voltage selector configured to receive a first gamma voltage, a second gamma voltage having a voltage level different from that of the first gamma voltage, and interpolation data, and configured to output a plurality of input voltages in accordance with the interpolation data and based on the first and second gamma voltages; and
an interpolation amplifier including,
a first input circuit including a first differential input pair configured to receive a first input voltage equal to the first gamma voltage among the plurality of input voltages, the first input circuit having a first transconductance value,
a second input circuit including a second differential input pair configured to receive a second input voltage corresponding to a least significant bit of the interpolation data among the plurality of input voltages, the second input circuit having a second transconductance value, and
a third input circuit including a third differential input pair configured to receive a third input voltage among the plurality of input voltages, the third input circuit having a third transconductance value,
wherein the first transconductance value and the second transconductance value are smaller than the third transconductance value.

2. The source driver of claim 1, wherein a magnitude of the first transconductance value is half of a magnitude of the second transconductance value.

3. The source driver of claim 1, wherein the interpolation data includes N bits (N is a natural number of 2 or more), and
the interpolation amplifier includes a plurality of differential input pairs less than 2^{N},
wherein the plurality of differential input pairs are configured to receive the plurality of input voltages, and the plurality of differential input pairs include the first differential input pair, the second differential input pair, and the third differential input pair.

4. The source driver of claim 3, wherein a number of all differential input pairs configured to receive the plurality of input voltages in the interpolation amplifier is 2^{(N-1)}+1.

5. The source driver of claim 1, wherein the first to third differential input pairs each include a first input transistor, a second input transistor, and a third input transistor configured to receive the first input voltage, the second input voltage and the third input voltage, respectively, and
a ratio of a channel width to a channel length of the first input transistor and the second input transistor is less than that of the third input transistor.

6. The source driver of claim 5, wherein the ratio of the channel width to the channel length of the first input transistor and the second input transistor is half of that of the third input transistor.

7. The source driver of claim 5, wherein the first input circuit, the second input circuit, and the third input circuit each further include a first current source, a second current source, and a third current source configured to generate a first bias current, a second bias current, and a third bias current, respectively, and
a magnitude of each of the first bias current and the second bias current is less than a magnitude of the third bias current.

8. The source driver of claim 7, wherein the ratio of the channel width to the channel length of the first input transistor and the second input transistor is half of that of the third input transistor, and
the magnitude of each of the first bias current and the second bias current is half of the magnitude of the third bias current.

9. The source driver of claim 1, wherein the first input circuit, the second input circuit, and the third input circuit each further include first current source, a second current source, and a third current source configured to generate first bias current, a second bias current, and a third bias current, respectively, and
a magnitude of each of the first bias current and the second bias current is less than a magnitude of the third bias current.

10. The source driver of claim 9, wherein the magnitude of each of the first bias current and the second bias current is half of the magnitude of the third bias current.

11. The source driver of claim 1, wherein the first input circuit and the second input circuit share a first current source that is configured to generate a first bias current.

12. A source driver comprising:
an interpolation amplifier configured to receive a plurality of input voltages repeatedly, the plurality of input voltages including at least one of a first gamma voltage or a second gamma voltage having a voltage level different from that of the first gamma voltage, and configured to generate an output voltage corresponding to interpolation data of N bits (N is a natural number of 2 or more) based on the plurality of input voltages, wherein
the interpolation amplifier includes a plurality of differential input pairs less than 2^{N},
the plurality of differential input pairs are configured to receive the plurality of input voltages,
the plurality of differential input pairs include
a first differential input pair including a first input transistor configured to receive a first input voltage of the plurality of input voltages,
a second differential input pair including a second input transistor configured to receive a second input voltage of the plurality of input voltages, and
a third differential input pair including a third input transistor configured to receive a third input voltage of the plurality of input voltages, and
a ratio of a channel width to a channel length of each of the first input transistor and the second input transistor is less than that of the third input transistor.

13. The source driver of claim 12, wherein a number of all differential input pairs configured to receive the plurality of input voltages in the interpolation amplifier is 2^{(N-1)}+1.

14. The source driver of claim 12, wherein the ratio of the channel width to the channel length of each of the first input transistor and the second input transistor is half of that of the third input transistor.

15. The source driver of claim 12, wherein the interpolation amplifier further includes a first current source that is connected to the first differential input pair in series and configured to generate a first bias current, a second current source that is connected to the second differential input pair in series and configured to generate a second bias current, and a third current source that is connected to the third differential input pair in series and configured to generate a third bias current, and
a magnitude of each of the first bias current and the second bias current is less than a magnitude of the third bias current.

16. The source driver of claim 15, wherein the magnitude of each of the first bias current and the second bias current is half of the magnitude of the third bias current.

17. The source driver of claim 12, wherein the interpolation amplifier further includes a first current source that is connected to the first differential input pair and the second differential input pair in series and configured to generate a first bias current, and a second current source that is connected to the third differential input pair in series and configured to generate a second bias current.

18. A source driver comprising:
an input voltage selector configured to receive a first gamma voltage, a second gamma voltage having a voltage level different from that of the first gamma voltage, and interpolation data, and configured to output a plurality of input voltages in accordance with the interpolation data and based on the first and second gamma voltages; and
an interpolation amplifier including a first input circuit including a first differential input pair configured to receive a first input voltage of the plurality of input voltages and a first current source configured to generate a first bias current, and a second input circuit including a second differential input pair configured to receive a second input voltage of the plurality of input voltages and a second current source configured to generate a second bias current, wherein
a ratio of a channel width to a channel length of a first input transistor of the first differential input pair is less than that of a second input transistor of the second differential input pair,
the first input transistor is configured to receive the first input voltage,
the second input transistor is configured to receive the second input voltage, and
a magnitude of the first bias current is less than a magnitude of the second bias current.

19. The source driver of claim 18, wherein the ratio of the channel width to the channel length of the first input transistor is half of that of the second input transistor.

20. The source driver of claim 19, wherein the magnitude of the first bias current is half of the magnitude of the second bias current.
